(19) United States
(12) Patent Application Publication
(10) Pub. No.: US 2019/0237391 A1
(43) Pub. Date: Aug. 1, 2019

(54) CHIP ASSEMBLIES EMPLOYING SOLDER BONDS TO BACK-SIDE LANDS INCLUDING AN ELECTROLYTIC NICKEL LAYER

(71) Applicant: Intel Corporation, Santa Clara, CA (US)

(72) Inventors: Seshu V. SATTIRAJU, Portland, OR (US); Krishna Prakash GANESAN, Portland, OR (US); Ashish BHATIA, Portland, OR (US); Vinay SRIRAM, Aloha, OR (US); John MUIRHEAD, Portland, OR (US); Hiten KOTHARI, Beaverton, OR (US); Aloysius A. GUNAWAN, Portland, OR (US); Lavanya ARYASOMAYAJULA, Hillsboro, OR (US); Shravan GOWRISHANKAR, Beaverton, OR (US); Sriram PATTABHIRAMAN, Hillsboro, OR (US); Sudipto GUHA, Hillsboro, OR (US)

(73) Assignee: Intel Corporation, Santa Clara, CA (US)

(21) Appl. No.: 16/329,170

(22) PCT Filed: Oct. 27, 2016
(86) PCT No.: PCT/US2016/054778

§ 371 Date: Feb. 27, 2019

(51) Int. Cl. H01L 23/48; H01L 21/768; H01L 25/18; H01L 23/00; H01L 23/522; H01L 23/528; H01L 21/822

(52) U.S. Cl. CPC H01L 23/481; H01L 2224/73203; H01L 21/76876; H01L 25/18; H01L 24/14; H01L 24/32; H01L 24/81; H01L 23/5226; H01L 23/5283; H01L 21/8221; H01L 24/73; H01L 2224/335; H01L 2224/175; H01L 2224/02373; H01L 2224/0231; H01L 2224/02381; H01L 21/76898

(57) ABSTRACT

A stacked-chip assembly including a plurality of IC chips or die that are stacked, and electrically coupled by solder bonds. In accordance with some embodiments described further below, the solder bonds are to contact a back-side land that includes a diffusion barrier to reduce intermetallic formation and/or other solder-induced reliability issues. The back-side land may include an electrolytic nickel (Ni) barrier layer separating solder from a back-side redistribution layer trace. This electrolytic Ni may be of high purity, which at least in part, may enable the backside metallization stack to be of minimal thickness while still functioning as a diffusion barrier. In some embodiments, the back-side land composition and architecture is distinct from a front-side land composition and/or architecture.

### BACKGROUND

There are many 3D integrated circuit (IC) chip, or die, technologies. A number of advanced 3DIC strategies include a plurality of IC chips in a stack to reduce the footprint of the IC chips and improve device density within a given platform (e.g., mobile device, computer, automobile).

Solder bonds are often employed in IC package attachment technologies, for example in flip-chip packaging, to electrically couple a front side of an IC chip to a substrate, such as a package substrate, interposer, or printed circuit board (PCB). One technique of stacking chips may also employ solder bonds to electrically couple stacked IC chips together. For a first IC chip that is to be front-side solder bonded, and also back-side solder bonded to a second IC chip, one challenge is keeping the total stacked IC chip height to a minimum so that the IC chip stack assembly is compatible with an ultra-thin form-factor platform, such as a mobile phone handset or ultrabook computer.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a cross-sectional view of a stacked-chip assembly including a first IC chip solder-bonded to a back-side land of a second IC chip, in accordance with some embodiments;

FIG. 2A illustrates an expanded cross-sectional view of an IC chip back-side land suitable for solder-bonding to another IC chip, in accordance with some embodiments;

FIG. 2B illustrates a top-down plan view of IC chip back-side metallization, in accordance with some embodiments;

FIG. 3 illustrates a flow diagram of methods for fabricating an IC chip back-side metallization architecture, in accordance with some embodiments;

FIGS. 4A, 4B, 4C, 4D, 4E, 4F, 4G, 4H, and 4I illustrate cross-sectional views of an IC back-side metallization architecture following the performance of operations in the methods illustrated in FIG. 3, in accordance with some embodiments;

FIG. 5 is a functional block diagram of an electronic computing device, in accordance with some embodiments; and

FIG. 6 illustrates a mobile computing platform and a data server machine, each employing a stacked-chip assembly including a first IC chip solder-bonded to a back-side land of a second IC chip, in accordance with some embodiments.

### DETAILED DESCRIPTION OF EXEMPLARY EMBODIMENTS

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings and are not intended to restrict the application of claimed subject matter. Therefore, the following detailed description is not to be taken in a limiting sense and the scope of claimed subject matter is defined solely by the appended claims and their equivalents.

In the following description, numerous details are set forth, however, it will be apparent to one skilled in the art, that embodiments may be practiced without these specific details. In some instances, well-known methods and devices are shown in block diagram form, rather than in detail, to avoid obscuring inventive aspects of the exemplary embodiments. References throughout this specification to “an embodiment” or “one embodiment” mean that a particular feature, structure, function, or characteristic described in connection with the embodiment is included in at least one embodiment. Thus, the appearances of the phrase “in an embodiment” or “in one embodiment” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the first and second embodiments are not mutually exclusive.

As used in the description of the exemplary embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

As described in greater detail below, a stacked-chip assembly includes a plurality of IC chips or die that are stacked together and electrically coupled to each other with solder bonds. Depending on the solder composition, interdiffusion at the interface of the solder and a redistribution layer (RDL) metal employed for backside routing on an IC chip may induce voiding within the RDL and/or solder feature, becoming a point of mechanical or electrical failure that can reduce reliability of the stack IC chip assembly. In accordance with some embodiments described further below, a back-side metal land structure includes a metallic diffusion barrier to reduce such metal diffusion across the back-side land. As described further below, the back-side land structure may include an electrolytic nickel (Ni) barrier layer that is to separate the solder from the RDL metal. In some advantageous embodiments, this electrolytic Ni layer is of high purity, which may enable the backside land to be of minimal thickness while still functioning as an adequate diffusion barrier over the expected lifetime of the chip assembly. As further described below, an IC chip's back-side land structure may be distinct from the land structure employed on a front side of the IC chip.

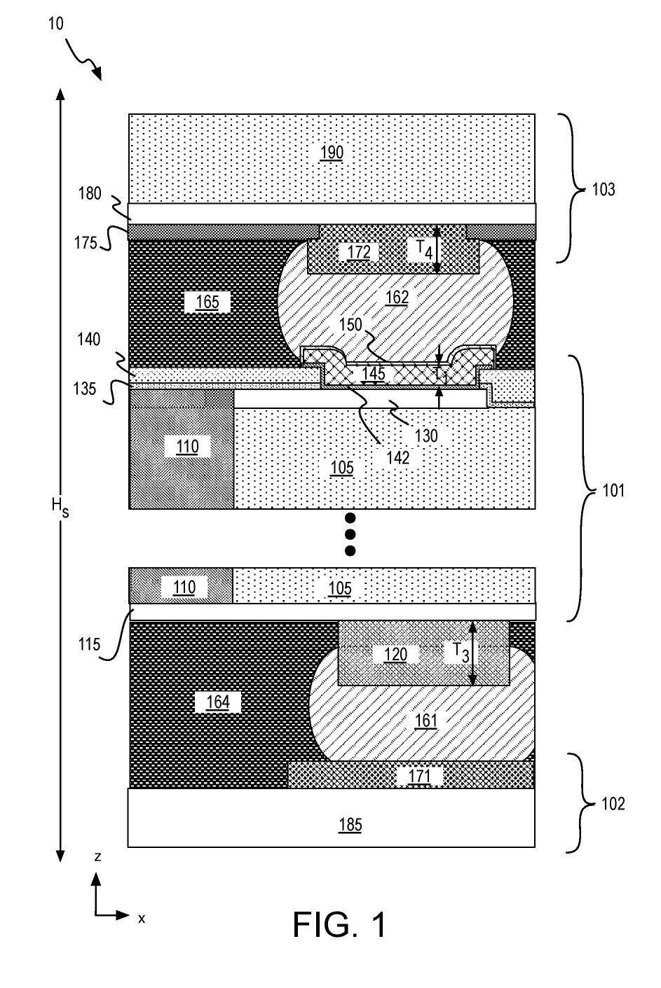

FIG. 1 illustrates a cross-sectional view of a stacked-chip assembly 10 including an IC chip 102 solder-bonded to a back-side solder land of an IC chip 101, in accordance with some embodiments. In these examples, front-side metallization of IC chip 101 is shown as further solder-bonded to a host substrate 102, in part to highlight differences between the front-side and back-side lands on IC chip 101. IC chip 101 may be an IC chip suitable for any application. In some exemplary embodiments, IC chip 101 includes microprocessor circuitry, including, for example, one or more processor cores, each further including groups of registers. IC chip 101 may further comprise a system-on-chip (SOC) that also includes one or more integrated cache memory arrays (e.g., SRAM) coupled to the processor cores through one or more one or more communication buses. IC chip 101 may further include one or more graphics processors further organized into execution units, texture samplers, encoder/decoder blocks, or media blocks, etc. IC chip 101 may further include, radio communication circuitry and/or SOC power management circuitry. In some such embodiments, IC chip 101 is a central processor chip suitable for executing one or more software applications, such as, but not limited to, a computer platform operating system.

IC chip 101 includes a substrate 105 that may be any substrate or carrier known to be suitable for the manufacture of integrated circuitry, such as, but not limited to wafers of semiconductor material(s). In some exemplary embodiments, substrate 105 is a crystalline silicon, germanium, group IV compound, or group III-V compound, semiconductor. In some other embodiments, substrate 105 is a stack of one or more layers of such semiconductors. Substrate 105 includes at least one device layer in which a plurality a semiconductor devices, such as, but not limited to transistors (e.g., MOSFETs), are fabricated. The semiconductor devices (not depicted in FIG. 1) may be fabricated in a front-side of IC chip 101 using any known techniques. The semiconductor devices are integrated together into an IC with one or more front-side interconnect metallization trace layers, a top-most front-side interconnect metallization trace 115 is shown in FIG. 1. Front-side interconnect metallization trace 115 may be, for example, Cu or a Cu alloy.

Substrate 105 may have been thinned (e.g., in z-dimension) to a thickness of less than 500 μm, advantageously less than 300 μm, and more advantageously 200 μm, or less. Thinning substrate 105 may advantageously relax the aspect ratio of through-substrate via (TSV) 110, which may for example, extend from one or more of the front-side interconnect metallization trace layers (e.g., shown in FIG. 1 to intersect top-most front-side interconnect metallization trace 115), through the thickness of substrate 105, and intersect a back-side surface of IC chip 101. The lateral critical dimension (CD) of TSV 110 can vary, and may be 50 μm, or less, for example. TSV 110 is filled with a conductive material, such as, but not limited to, Cu/Cu alloy that has been plated according to any known techniques, for example from the back-side of substrate 105 during back-side processing of IC chip 101. TSV 110 is electrically coupled to a conductive back-RDL trace 130 that extends laterally (e.g., in the x-dimension) away from TSV 110. Back-side RDL trace 130 may have any composition, and may be, for example, any metal/metal alloy. In some embodiments, back-side RDL trace 130 has the same composition as top-most front-side interconnect metallization trace 115 (e.g., Cu/Cu alloy). The thickness of back-side RDL trace 130 can vary, with exemplary embodiments having a thickness of 2-10 μm.

Top-most front-side interconnect metallization trace 115 is in contact with a front-side land 120. Front-side land 120 is to locate and interface with a first solder feature 161 during front-side bonding of IC chip 101 to a host substrate 102. Front-side bonding of IC chip 101 may employ any known technology, such as, but not limited to, flip-chip bonding technology. Host substrate 102 may be any package substrate, interposer, or printed circuit board, etc. as embodiments herein are not limited in this context. Solder feature 161 may be a solder ball, microball, bump, microbump, post, pillar, or other feature. Solder feature 161 may have any composition known to be suitable for the interconnection of an IC chip to a host substrate. In some embodiments, solder feature 161 is any Sn/Ag/Cu (SAC) alloy. Solder feature 161 joins front-side land 120 to a host substrate land 171. Other regions of IC chip 101 and host substrate 102 are electrically insulated from solder feature 161 by backfill material 164. Backfill material 164 may be any known epoxy/filler, for example.

Front-side land 120 may include one or more metal layers and have a thickness T₃ (i.e., height in the z-dimension). In some embodiments, front-side land 120 comprises a Co/Co alloy layer. In some such embodiments, the Co alloy layer is an electroless Co alloy, which may be readily identified as having a significant concentration (e.g., 10 atomic %, or more) of impurities, such as phosphorus (P). Other metals are also possible, and if also electroless can be expected to have similar impurity levels. (e.g., 10%). In some further embodiments, front-side land 120 has a thickness T₃ that is at least 8 μm, and may be 10-15 μm, or more. This substantial land thickness may advantageously retard interdiffusion between solder feature 161 and top-most front-side interconnect metallization trace 115, particularly where front-side land 120 comprises an electroless alloy with significant impurity levels.

IC chip 101 is further electrically coupled to a second IC chip 103 through back-side RDL trace 130. While IC chip 103 may include any integrated circuitry, in some advantageous embodiments where IC chip 101 is a microprocessor, IC chip 103 is memory chip. In memory chip embodiments, IC chip 103 may include a memory cell array, such as, but not limited to, DRAM memory cells, as well as memory array management circuitry. IC chip 103 includes a substrate 190 (e.g., silicon semiconductor), at least a front-side of which includes semiconductor devices (e.g., memory cells, and logic transistors) interconnected into circuitry by one or more front-side metallization trace layers. A top-most front-side interconnect trace 180 is electrically connected to a land 172. Land 172 is surround by a dielectric material 175, which, along with backfill material 165, electrically insulates select portions of IC chip 103 from solder feature 162. Backfill material 165 may be any known epoxy/filler, for example.

Solder feature 162 may be a solder ball, microball, bump, microbump, post, pillar, or other feature. Solder feature 162 may have any composition known to be suitable for the interconnection of two IC chips. In some embodiments, solder feature 162 is any Sn/Ag/Cu (SAC) alloy. Solder feature 162 joins back-side RDL trace 130 to IC chip 103 through a back-side land that includes one or more metal layer absent from front-side land 120. The back-side land is disposed within an opening defined in one or more layer of dielectric material. In the exemplary embodiment, this dielectric material includes a first conformal dielectric layer 135 in contact with RDL trace 130, and a second planarizing dielectric layer 140 disposed over conformal dielectric layer 135.

In the illustrated embodiments, the back-side land includes a Ni layer 145 that is absent from front-side land 120. In some advantageous embodiments, Ni layer 145 accounts for the majority of the thickness of the back-side land disposed over RDL trace 130. Ni layer 145 may have a maximum thickness T₁ that is significantly less than front-side land thickness T₃, which may advantageously reduce the total stacked assembly height Hs. The Ni thickness T₁ may be less than half front-side land thickness T₃, for example. In some exemplary embodiments, Ni layer thickness T₃ is less than 5 μm, and may be as thin as 2-4 μm. The back-side land may further include one or more adhesion and/or seed layers 138 disposed between Ni layer 145 and back-side RDL trace 130. As further illustrated in FIG. 1, the back-side land may further include one or more surface finish layers 150 disposed between Ni layer 145 and solder feature 162. In some embodiments, back-side adhesion and/or seed layers 138 and back-side surface finish layer 150 are of metal compositions and/or of thicknesses that make them unsuitable as diffusion barriers. Hence, back-side Ni layer 145 is relied upon for retarding interdiffusion between solder feature 162 and back-side RDL trace 130 sufficiently to avoid significant voiding within at least back-side RDL trace 130 over the expected lifetime of assembly 10 at the expected operating conditions of assembly 10.

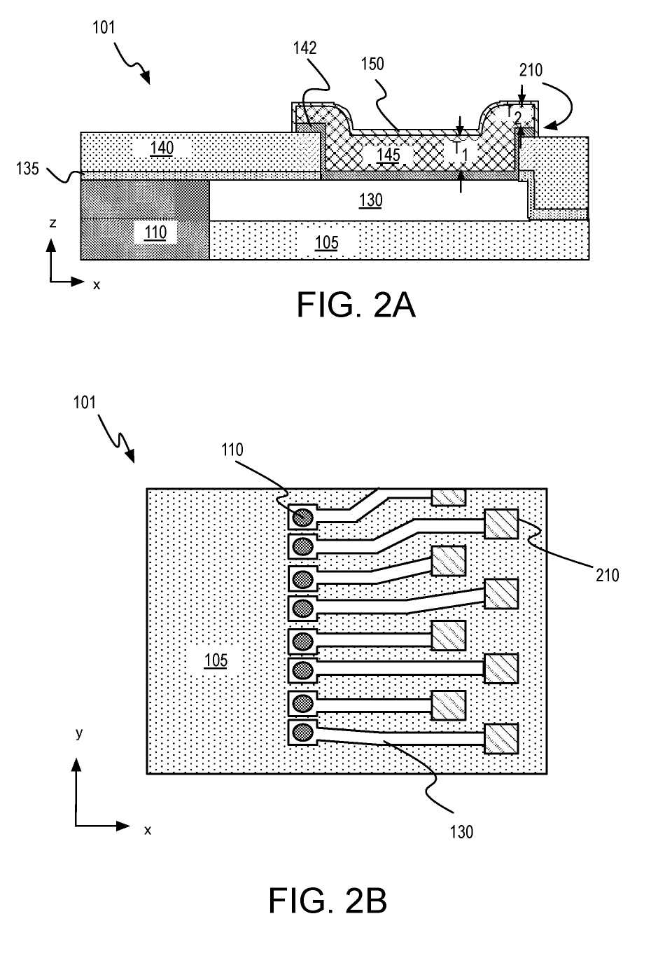

FIG. 2A illustrates an expanded cross-sectional view of IC chip 101, in accordance with some embodiments. As shown, a land opening is defined by sidewalls of a dielectric material layers 135 and 140. Passivation dielectric material layer 135 is conformal, having a thickness on a sidewall surface of RDL trace 130 that is at least 80% of the nominal thickness over a top surface of RDL trace 130. Passivation dielectric material layer 135 may have a nominal thickness less than 1 μm (e.g., 100-500 nm) and be any of SiC, SiN, SiCN, SiO, SiON, or SiOC, for example. A planarizing dielectric material layer 140 is disposed over passivation dielectric material layer 135. Planarizing dielectric material layer 140 may be any of SiC, SiN, SiCN, SiO, SiON, SiOC, HSQ, MSQ, or the like, for example. In some advantageously embodiments however, planarizing dielectric material layer 140 is a photo-definable dielectric, such as but not limited to SU-8, or similar permanent photoresist. Planarizing dielectric material layer 140 may have a nominal thickness of 3-5 μm, for example. As further illustrated in FIG. 2A, the sidewall of planarizing dielectric material layer 140 is aligned with the sidewall of passivation dielectric material layer 135.

Back-side adhesion and/or seed layer 142 contacts the dielectric material sidewalls, contacts the surface of RDL trace 130 exposed within the land opening, and overlaps onto a portion of planarizing dielectric material layer 140. In some embodiments, back-side adhesion and/or seed layer 142 includes an adhesion layer comprising Ti in direct contact with RDL trace 130, a sidewall of passivation dielectric 135, a sidewall of planarizing dielectric layer 140, and a top surface of planarizing dielectric layer 140. The Ti adhesion layer may, for example, have a nominal thickness of 50-100 nm. In some embodiments, back-side adhesion and/or seed layer 142 further includes a seed layer, for example comprising predominantly Cu, having a nominal thickness of 100-500 nm, or more. This seed layer may, for example, be in direct contact with the adhesion layer.

Ni layer 145 is in direct contact with back-side adhesion and/or seed layer 142 and may have been electrolyticly plated onto back-side adhesion and/or seed layer 142, for example as described further below. Electrolytic plating is one technique that can deposit Ni layer 145 with a high purity, for example of at least 97% (atomic) Ni. Such a high purity has been found by the inventors to render Ni layer 145 an excellent barrier to the interdiffusion of one or more metals in RDL trace 130 and/or one or more metals in solder feature 162. In particular, the inventors have found Ni layer 145, with a purity significantly higher than 90%, is an excellent barrier to the diffusion of Cu from RDL trace 130 otherwise promoted by the presence of Sn in solder feature 162. With a purity of at least 97% Ni, the inventors have found that Ni layer 145 may be as thin as 2 μm and the back-side land can pass the same reliability criteria as front-side land 120 having the much greater thickness T₃. Depending on the composition of lands on IC chip 103, Ni layer 145 may also be thinner than the land thickness T₄ associated with IC chip 103. For example, where land 172 is other than 97% Ni, T₄ may be many microns thicker than Ni thickness Ti.

As further illustrated in FIG. 2A, Ni layer 145 has a sidewall aligned with the sidewall of back-side adhesion and/or seed layer 142. Such alignment is indicative of a masked Ni plating process, for example as described further below. Following such a mask plating process, the back-side adhesion and/or seed layer 142 may be stripped with Ni layer 145 serving as a mask, as further described below. In some embodiments where Ni layer 145 is electrolyticly deposited, the back-side land opening may be superfilled with the portion of Ni layer 145 disposed over RDL trace 130 having a Ni thickness Ti, which is greater than the Ni thickness T₂ at the portion of Ni layer 145 overlapping dielectric material layers 135, 140.

As further illustrated in FIG. 2A, Ni layer 145 may be encapsulated in a conductive passivation layer, such as gold passivation layer 150, to prevent oxidation of Ni layer 145 that might otherwise hinder solder feature 162 wetting the back-side land. Other noble metals may also be employed as an alternative passivation layer. In some embodiments, gold passivation layer 150 has a nominal thickness of 10-50 nm. Gold passivation layer 150 may also be in direct contact with the adhesion and/or seed layer sidewall 210 to completely encapsulate the back-side land. As described further below, gold passivation layer 150 may be selectively deposited onto the back-side land through electroless deposition, in which case, gold passivation layer 150 may include a number of impurities at the PPM level.

FIG. 2B illustrates a top-down plan view of IC chip back-side metallization, in accordance with some embodiments. As shown, back-side metallization of IC chip 101 includes a plurality of RDL traces 130 each extending laterally from at least one TSV 110 to at least one back-side land fully encapsulated with gold passivation layer 150. Back-side lands may have a predetermined pitch and spatial location to align with lands present on a second IC chip, such as IC chip 103 illustrated in FIG. 1.

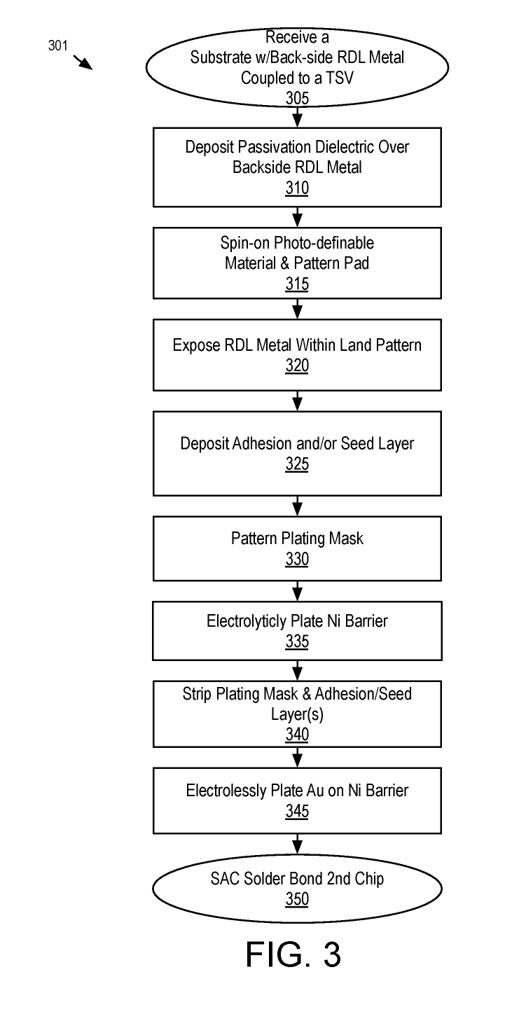

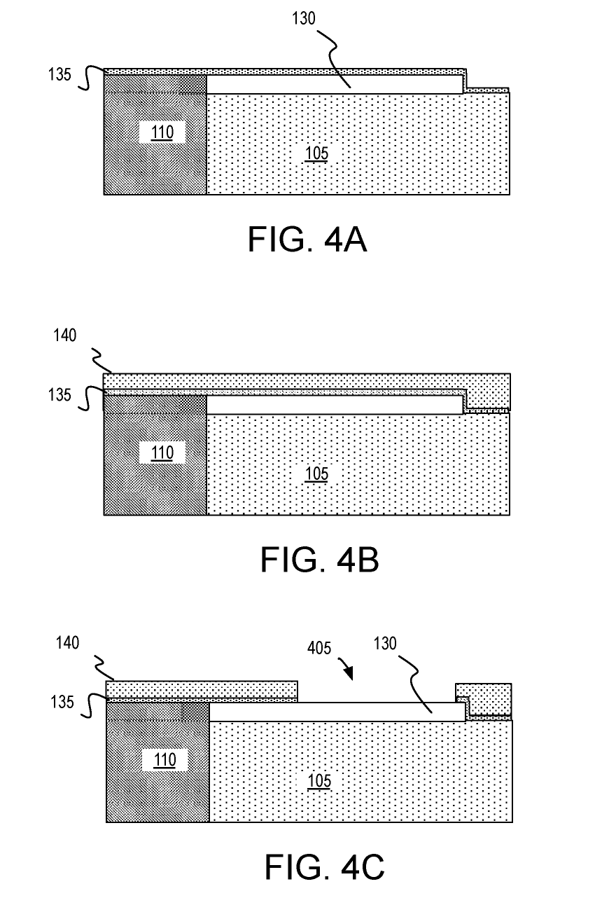

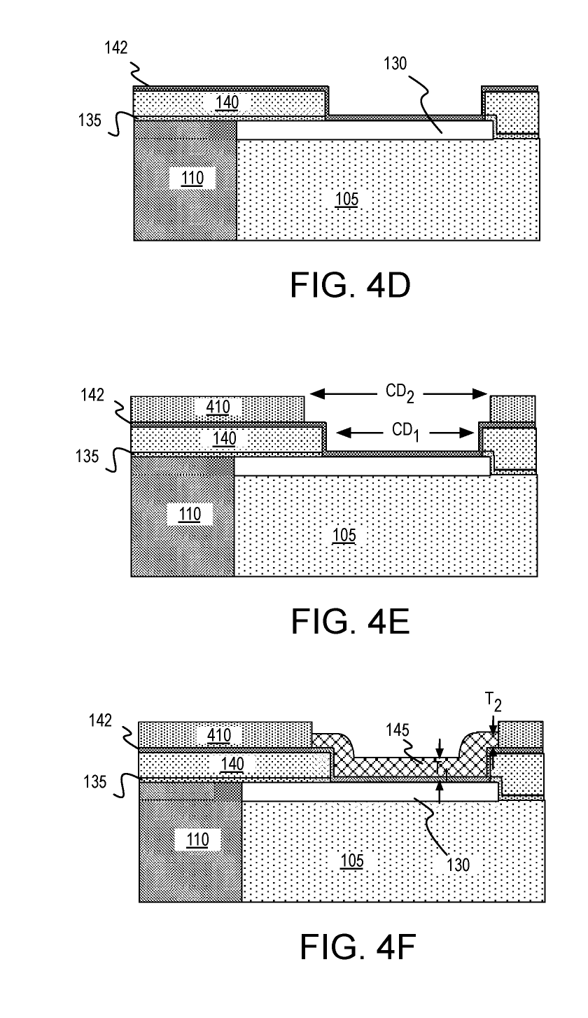

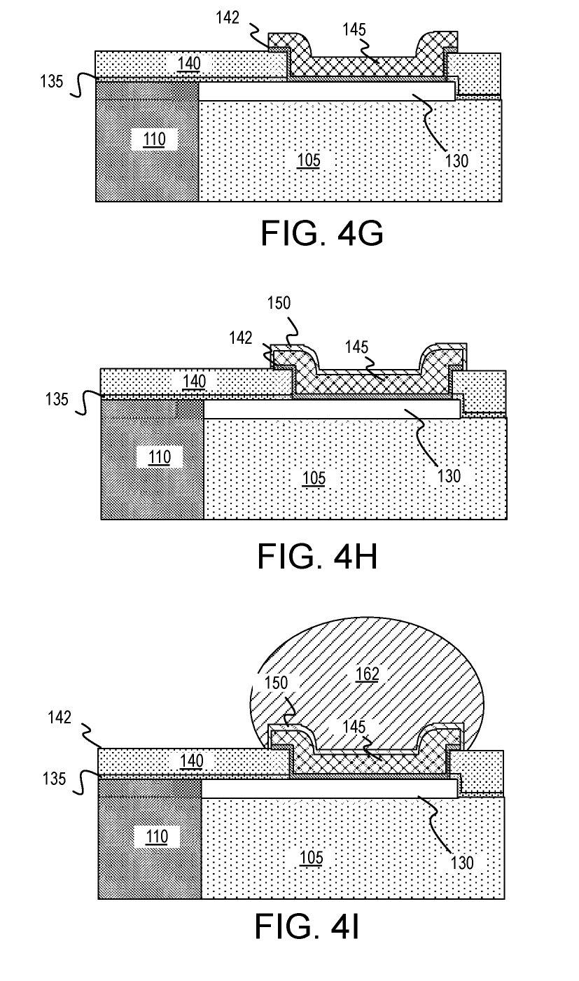

FIG. 3 illustrates a flow diagram of methods 301 for fabricating an IC chip back-side metallization architecture, in accordance with some embodiments. FIG. 4A-4I illustrate cross-sectional views of an IC back-side metallization architecture following the performance of operations in the methods 301, in accordance with some embodiments. Referring first to FIG. 3, methods 301 begin at operation 305 where a substrate having back-side RDL traces coupled to TSVs is received. One or more layers of dielectric material are then deposited over the back-side RDL traces. These dielectric material layer(s) are to provide a top-most electrical insulation and/or a hermetic seal over the back-side of the substrate, RDL and TSVs. In some exemplary embodiments, the dielectric material deposited over the RDL traces includes at least a first layer of passivation dielectric material that is deposited conformally at operation 310.

In the example further shown in FIG. 4A, back-side passivation dielectric material layer 135 is conformally deposited over RDL trace 130. RDL trace 130 extends laterally over substrate 105 and is electrically coupled to TSV 110. As described above, substrate 105 may be a semiconductor wafer (e.g. 300-450 mm diameter). Substrate 105 may further include semiconductor devices (not depicted in FIG. 4A), such as transistors (e.g., MOSFETs) that are interconnected into integrated circuitry (e.g., CMOS) by levels of front-side interconnect metallization (not depicted in FIG. 4A). In some exemplary embodiments, the back-side RDL trace 130 comprises Cu or a Cu alloy that has been deposited over a back side of substrate 105. As deposited, RDL trace 130 may be in contact with a back-side insulation dielectric layer, such as silicon dioxide, silicon nitride, silicon oxynitride, low-k dielectric, or the like. The back-side RDL trace 130 may have a thickness of 1-10 μm, for example. Back-side passivation dielectric material layer 135 may be conformally deposited, for example, by chemical vapor deposition (CVD), plasma-enhanced CVD (PECVD), atomic layer deposition (ALD) process. Exemplary materials for back-side passivation dielectric material layer 135, include, but are not limited to, SiC, SiN, SiCN, SiO, SiON, or SiOC. Back-side passivation dielectric material layer 135 may be deposited to a nominal thickness less than 1 μm (e.g., 100-500 nm).

The dielectric material deposited over the back-side RDL trace may include a stack of two or more materials of distinct composition. In some such embodiments, a planarizing and/or flowable dielectric material layer is deposited over the passivation dielectric material layer at operation 315. The planarizing dielectric may, for example, be a photo-definable dielectric that can be exposed and developed in any manner known in the art at to define a back-side land pattern. An etch process may then be employed at operation 320 to remove the first dielectric layer and expose a portion of the RDL trace within the patterned land opening. In the example further illustrated in FIG. 4B, a planarizing dielectric layer 140 is deposited, for example with a spin-on process. Planarizing dielectric layer 140 may be of a photo-definable composition, such as, but not limited to SU-8, or similar permanent photoresist. Planarizing dielectric layer 140 may be deposited to a thickness sufficient to cover the RDL trace with 100-500 nm of material, for example. In some such embodiments, the planarizing dielectric layer 140 may be deposited to a nominal thickness of 3-5 μm over the back side of the substrate. As shown in FIG. 4C, following exposure and develop, back-side passivation dielectric material layer 135 is etched, for example with any wet etch or plasma dry etch know to be suitable for the dielectric material composition, to pattern a land opening 405 over a portion of RLD trace 130 in alignment with the opening in dielectric layer 140.

Returning to FIG. 3, methods 301 continue at operation 325 where a back-side adhesion layer and/or a back-side conductive seed layer is deposited over the back-side dielectric and over the back-side RDL trace exposed within the land openings. One or more materials may be deposited as the adhesion layer and one or more materials may be deposited as the conductive seed layer. In the example further shown in FIG. 4D, back-side adhesion layer and/or a back-side conductive seed layer 142 is deposited over back-side RDL trace 130 and over planarizing dielectric layer 140. In some exemplary embodiments, an adhesion layer comprising Ti is deposited directly on the exposed portion of back-side RDL trace 130 and on planarizing dielectric layer 140. In some embodiments, the adhesion layer is deposited with a CVD process or a physical vapor deposition (PVD) process to a nominal thickness of 50-100 nm. A seed layer, (e.g., comprising predominantly Cu), may then be deposited, for example with any known electroless plating process, to a thickness of 100-500 nm, or more.

Methods 301 (FIG. 3) continue at operation 330 where a plating mask is formed over the adhesion and/or seed layer. The plating mask is to be patterned to having mask openings aligned with the land openings patterned at operation 315. In some embodiments, the plating mask is patterned to have a lateral opening diameter that is larger than that of the land opening patterned at operation 315 so that sidewalls of the plating mask overly the back-side dielectric material. In some embodiments, the plating mask is sacrificial and of a material that may be subsequently stripped selectively to the back-side dielectric material. While the plating mask may be in the form of a dielectric hardmask material that is pattern etched, in an advantageous embodiment, the plating mask material is a photoresist that is lithographically printed (exposed) and developed, as further illustrated in FIG. 4E. As shown, lateral CD₂ of the plating mask opening is larger than lateral CD₁ of the land opening. The difference between CD₂ and CD₁ is sufficient to accommodate overlay error, for example.

Returning to FIG. 3, methods 301 continue at operation 335 where a high-purity Ni layer is deposited with a through-resist electrolytic plating process. In the example illustrated in FIG. 4F, Ni layer 145 is plated onto exposed regions of adhesion layer and/or seed layer 142 within the plating mask window. In some embodiments, the electrolytic Ni plating process employed at operation 335 deposits Ni to a purity of at least 97%. Notably, the Ni plating process is superfilling, with the thickness of Ni layer 145 within a portion of the plating mask opening overlapping the land window achieving at least a Ni thickness Ti, which is greater than the Ni thickness T₂ at the periphery of the plating mask opening overlapping the back-side dielectric material layers 135, 140. The Ni thickness Ti plated at operation 335 may vary, with thicknesses in the range of 2-5 μm being advantageous for minimizing the land height while still providing an adequate diffusion barrier over RDL trace 130. In the example shown in FIG. 4F, Ni layer 145 is deposited to a thickness that is less than the nominal thickness of plating mask 410, and to a thickness insufficient for Ni layer 145 to become planarized within the plating mask opening.

Returning to FIG. 3, methods 301 continue at operation 340 where the plating mask is stripped. The adhesion and/or conductive seed layers may then be stripped at operation 340, as masked by the electrolytic Ni layer, to expose the back-side dielectric material. In the example shown in FIG. 4G, planarizing dielectric layer 140 is exposed following the strip or ash of plating mask 410. A wet chemical etch may be employed to remove the conductive seed layer, and a wet chemical and/or dry plasma etch may be employed to remove the adhesion layer, as needed, using any technique known in the art to be suitable for the material compositions.

Methods 301 (FIG. 3) continue at operation 345 where a noble metal passivation layer is deposited over the electrolytic Ni layer to complete the back-side land architecture. Either platinum, or gold, for example, may be deposited at operation 345. In some advantageous embodiments further illustrated in FIG. 4H, a gold passivation layer 150 is deposited electrolessly onto electrolytic Ni layer 145, thereby covering all exposed Ni surfaces. Electroless deposition may advantageously form gold passivation layer 150 on exposed metal surfaces selectively over dielectric materials 135, 140. Gold passivation layer 150 may be deposited to a nominal thickness of 10-50 nm, for example. As further illustrated, gold passivation layer 150 is also deposited onto exposed sidewalls of adhesion and/or seed layer 142. Hence, in some examples where adhesion and/or seed layer 142 includes both Ti adhesion layer and a Cu seed layer, gold passivation layer 150 is in direct contact with all three of these metal layers to completely encapsulate the multi-layered land structure.

Returning to FIG. 3, methods 301 complete with forming a solder bond to the back-side land. In the exemplary embodiment, a second IC chip is solder-bonded to the back-side land. All though any suitable solder formulation may be employed, in some advantageous embodiments a solder comprising Sn, such as any known Sn—Ag—C(SAC) solder alloy, is employed. As further shown in the example of FIG. 4I, a SAC solder feature 162 makes direct contact with the back-side land. As noted elsewhere herein, the inventors have found that the presence of electrolytic Ni layer 145 separating RLD 130 from SAC solder features 162 will retard interdiffusion of metal species between solder feature 162 and/or RDL trace 130 sufficiently to prevent the formation of voids at least within RDL trace 130 that are often indicative of Cu migration into a solder feature.

Following the completion of methods 301, any of the IC chip assemblies described elsewhere herein may be assembled using any techniques known in the package assembly art.

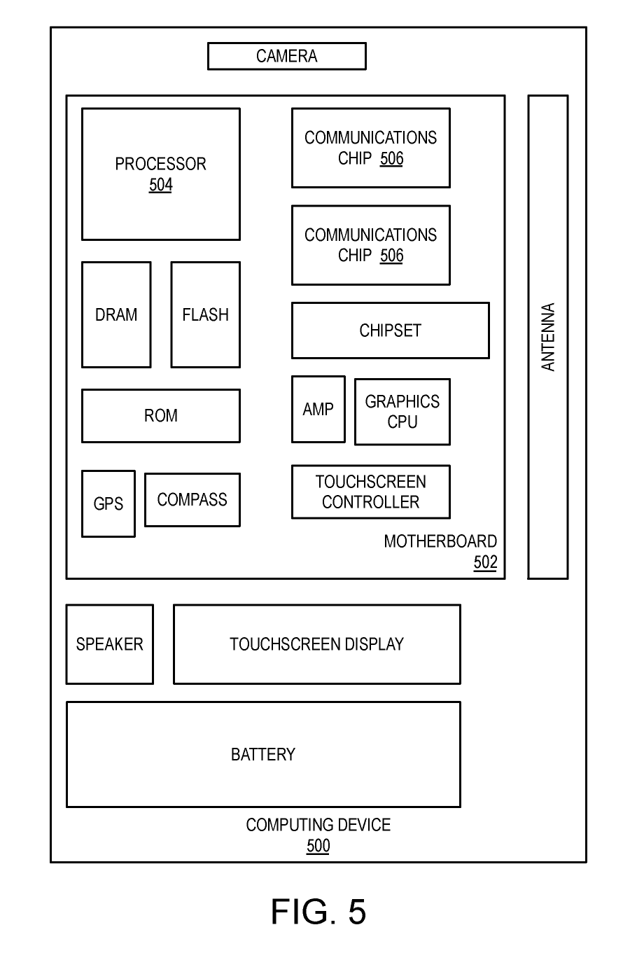

FIG. 5 is a functional block diagram of an electronic computing device, in accordance with an embodiment of the present invention. Device 500 further includes a motherboard 502 hosting a number of components, such as, but not limited to, microprocessor circuitry 504 (e.g., an applications processor). Processor circuitry 504 may be physically and/or electrically coupled to motherboard 502. In general, the term “processor” or “microprocessor” may refer to any device or portion of a device that processes electronic data from registers and/or memory to transform that electronic data into other electronic data that may be further stored in registers and/or memory.

In various examples, one or more communication chips 506 may also be physically and/or electrically coupled to the motherboard 502. In further implementations, communication chips 506 may be part of processor 504. Depending on its applications, computing device 500 may include other components that may or may not be physically and electrically coupled to motherboard 502. These other components include, but are not limited to, volatile memory (e.g., DRAM), non-volatile memory (e.g., ROM), flash memory (e.g., NAND or NOR), a graphics processor, a digital signal processor, a crypto processor, a chipset, an antenna, touchscreen display, touchscreen controller, battery, audio codec, video codec, power amplifier, global positioning system (GPS) device, compass, accelerometer, gyroscope, speaker, camera, and mass storage device (such as hard disk drive, solid-state drive (SSD), compact disk (CD), digital versatile disk (DVD), and so forth), or the like. In some exemplary embodiments, at least the flash memory comprises a stacked-chip assembly including stacked leads, for example as described elsewhere herein.

Communication chips 506 may enable wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they do not. Communication chips 506 may implement any of a number of wireless standards or protocols, including but not limited to those described elsewhere herein. As discussed, computing device 500 may include a plurality of communication chips 506. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

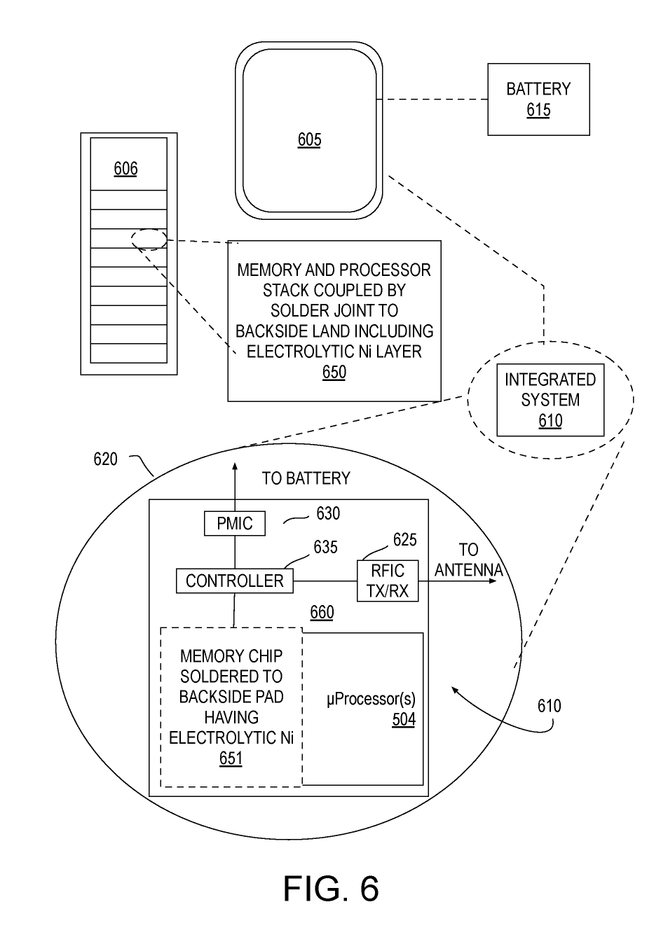

FIG. 6 illustrates a mobile computing platform and a data server machine employing a stacked-chip assembly including a first IC chip solder-bonded to back-side metallization of a second IC chip, in accordance with some embodiments. In advantageously embodiments, the first IC chip is a memory chip and the second IC chip includes a microprocessor. The solder bond between the first and second chip interfaces to a back-side land on the second IC chip that includes an electrolytic Ni layer, for example as described elsewhere herein. Computing device 500 may be found inside platform 605 or server machine 606, for example. The server machine 606 may be any commercial server, for example including any number of high-performance computing platforms disposed within a rack and networked together for electronic data processing. In some embodiments, server machine 606 includes a memory chip and processor chip stack 650, which is coupled together by a solder joint to a backside land of one of the chips that includes an electrolytic Ni layer. Stacked-chip assembly 650 may include one chip with at least memory cell array circuitry, such as any known dynamic RAM (DRAM) array circuitry, for example, solder bonded to a host chip, for example including microprocessor circuitry.

The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), a chip-level or package-level integrated system 610, and a battery 615. Integrated system 610 may includes a system on chip (SOC) 660 that includes microprocessor circuitry 504 and one or more of a power management integrated circuitry (PMIC) 630, RF (wireless) integrated circuitry (RFIC) 625 including a wideband RF (wireless) transmitter and/or receiver (TX/RX) (e.g., including a digital baseband and an analog front end module that further comprises a power amplifier on a transmit path and a low noise amplifier on a receive path), and a controller 635. Solder bonded to a backside of SOC 660 is memory chip 651. Memory chip 651 may be a DRAM chip or other known volatile or non-volatile memory array circuitry. Memory chip 651 is solder bonded to lands on a back side of SOC 660. These back-side lands include an electrolytic Ni layer, for example as described elsewhere herein.

Functionally, PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

In one or more embodiments, an integrated circuit (IC) chip comprises a substrate including a plurality of transistors, and one or more front-side metallization layers disposed over a front side of the substrate, the front-side metallization layers electrically coupled to one or more of the transistors. The IC chip comprises a front-side land electrically coupled to the front-side metallization layers, and to receive a front-side solder feature. The IC chip comprises a through-substrate via (TSV) extending through the substrate, the TSV with a first end coupled to at least one of the front-side metallization layers. The IC chip comprises one or more back-side metallization layers disposed over a back-side of the substrate, the back-side metallization layers including a metal redistribution layer (RDL) trace electrically coupled to the TSV. The IC chip includes a back-side land electrically coupled to the back-side metallization layers, and to receive a back-side solder feature, wherein the back-side land includes an electrolytic Ni layer disposed over the RDL trace.

In one or more second embodiments, for any of the first embodiments of the IC chip the RDL trace comprises a Cu alloy, and the electrolytic Ni layer has purity of at least 97% Ni.

In one or more third embodiments, for any of the first or second embodiments of the IC chip, the land further comprises an adhesion layer in contact with the RDL trace, and a seed layer comprising Cu disposed between the electrolytic Ni layer and the adhesion layer.

In one or more fourth embodiments, for any of the first, second, or third embodiments of the IC chip, the RDL trace has a thickness of 2-10 μm, and the electrolytic Ni layer has a thickness less than 5 μm.

In one or more fifth embodiments, in any of the third embodiments the adhesion layer comprises Ti, and has a thickness less than 0.1 μm, and the seed layer has a thickness less than 0.5 μm.

In one or more sixth embodiments, in any of the first, second, third, fourth, or fifth embodiments of the IC chip, the front-side land comprises a metal layer having a composition other than 97% Ni and of a thickness at least twice that of the electrolytic Ni layer.

In one or more seventh embodiments, in any of the sixth embodiments the front-side land comprises an electroless metal layer in contact with a front-side trace comprising a Cu alloy, the electroless metal layer having a thickness of at least 10 μm, and the electrolytic Ni layer thickness is less than 5 μm.

In one or more eighth embodiments, in any of the first, second, third, fourth, fifth, sixth, or seventh embodiments of the IC chip the land covers an opening extending through one or more dielectric layers disposed over the RDL trace, the electrolytic Ni layer overlapping a portion of the dielectric layers.

In one or more ninth embodiments, for any of the first, second, third, fourth, fifth, sixth, seventh, or eighth embodiments of the IC chip, an electroless noble metal layer is disposed on sidewalls of at least the electrolytic Ni layer.

In one or more tenth embodiments, in any of the ninth embodiments of the IC chip the adhesion layer contacts the RDL trace within the opening, and the electrolytic Ni layer, seed layer, and adhesion layer all overlap the dielectric layers by the same amount along the entire perimeter of the land, and the electroless noble metal layer comprises a Au layer disposed on sidewalls of the Ni layer, seed layer, and adhesion layer.

In one or more eleventh embodiments, an integrated circuit (IC) chip assembly includes a memory chip further comprising a first substrate including a plurality of memory cells, a first metal trace coupled to one or more of the memory cells, and disposed over a first side of a first substrate, and a first land disposed between the first metal trace and a first solder joint. The IC chip assembly further includes a microprocessor chip further comprising a second substrate including a plurality of transistors, one or more front-side metallization layers disposed over a front side of the second substrate, the front-side metallization layers electrically coupled to one or more of the transistors, a front-side land electrically coupled to the front-side metallization layers, and to receive a front-side solder feature, a through-substrate via (TSV) extending through the second substrate, the TSV with a first end coupled to at least one of the front-side metallization layers, one or more back-side metallization layers disposed over a back-side of the second substrate, the back-side metallization layers including a metal redistribution layer (RDL) trace electrically coupled to the TSV, and a back-side land electrically coupled to the back-side metallization layers and connected to the first solder joint, wherein the back-side land includes an electrolytic Ni layer disposed over the RDL trace.

In one or more twelfth embodiments, in any of the eleventh embodiments of the IC chip assembly of claim 11, the first and second solder joints comprise Sn, Ag and Cu, the RDL trace comprises a Cu alloy, the electrolytic Ni layer has purity of at least 97% Ni, the first land and the front-side land each comprise a metal layer having a composition other than 97% Ni and of a thickness at least twice that of the electrolytic Ni layer.

In one or more thirteenth embodiments, in any of the eleventh or twelfth embodiments of the IC chip assembly the first land and the front-side land each comprise an electroless metal layer.

In one or more of fourteenth embodiments, in any of the eleventh, twelfth, or thirteenth embodiments of the IC chip assembly further comprise a second solder joint comprising Sn, Ag, and Cu in contact with the front-side land, and wherein the front-side land comprises Co.

In one or more fifteenth embodiments, a method of fabricating an integrated circuit (IC) chip comprises receiving a substrate with a back-side redistribution layer (RDL) trace coupled to a through-substrate via (TSV), depositing one or more dielectric material layers over the back-side RDL trace, exposing a portion of the back-side RDL trace by etching through the dielectric material layers within a back-side land pattern, depositing one or more metal seed layers over the exposed portion of the RDL trace and over the dielectric material layers, patterning a plating mask to have an opening exposing the metal seed layers within the back-side land pattern, electrolyticly depositing a Ni metal layer within the opening to form a back-side land over the RDL trace, stripping the plating mask and seed layers, and electrolessly depositing a noble metal layer over the Ni metal layer.

In on or more sixteenth embodiments, in any of the fifteenth embodiments of the method, the method further comprises forming one or more front-side metallization layers over a front side of the substrate, the front-side metallization layers electrically coupled to one or more of transistors. The method further comprises forming a front-side land electrically coupled to the front-side metallization layers, and to receive a front-side solder feature. The method further comprises forming the TSV with a first end coupled to at least one of the front-side metallization layers, and forming the back-side RDL trace, wherein the back-side RDL trace comprises a Cu alloy of 2-10 μm in thickness, and the Ni layer has purity of at least 97% Ni and a thickness less than 5 μm.

In one or more seventeenth embodiments, for any of the thirteenth, fourteenth, fifteenth, or sixteenth embodiments of the method forming the front-side land further comprises depositing a metal layer having a composition other than 97% Ni and of a thickness at least twice that of the Ni layer.

In one or more eighteenth embodiments, any of the thirteenth, fourteenth, fifteenth, sixteenth, or seventeenth embodiments of the method further comprise solder bonding the back-side land to a memory chip with a solder comprising Sn, Ag, and Cu, and solder bonding the front-side land to a host substrate with a solder comprising Sn, Ag, and Cu.

In one or ore nineteenth embodiments, in any of the thirteenth, fourteenth, fifteenth, sixteenth, seventeenth or eighteenth embodiments depositing the one or more metal seed layers further comprises depositing an adhesion layer in contact with the RDL trace, and depositing a seed layer comprising Cu over the adhesion layer.

In one or ore twentieth embodiments, in any of the thirteenth, fourteenth, fifteenth, sixteenth, seventeenth, eighteenth, or nineteenth embodiments depositing the one or more dielectric material layers further comprises depositing a first dielectric layer with a chemical vapor deposition process, and depositing a photo-definable dielectric layer over the first dielectric layer with a spin-on deposition process, and exposing a portion of the RDL trace further comprises exposing and developing the land pattern into the photo-definable dielectric layer, and etching through a portion of the first dielectric layer unprotected by the photo-definable dielectric layer with a wet chemical or dry plasma etch process.

It will be recognized that the invention is not limited to the embodiments so described, but can be practiced with modification and alteration without departing from the scope of the appended claims. For example the above embodiments may include specific combinations of features as further provided below.

1-20. (canceled)

21. An integrated circuit (IC) chip, comprising:
a substrate including a plurality of transistors;
one or more front-side metallization layers over a front side of the substrate, the front-side metallization layers electrically coupled to one or more of the transistors;
a front-side land electrically coupled to the front-side metallization layers, and to receive a front-side solder feature;
a through-substrate via (TSV) extending through the substrate, the TSV with a first end coupled to at least one of the front-side metallization layers;
one or more back-side metallization layers over a back-side of the substrate, the back-side metallization layers including a metal redistribution layer (RDL) trace electrically coupled to the TSV; and
a back-side land electrically coupled to the back-side metallization layers, and to receive a back-side solder feature, wherein the back-side land includes a layer comprising Ni that is over the RDL trace.

22. The IC chip of claim 21, wherein:
the RDL trace comprises a Cu alloy; and
the layer comprising Ni has purity of at least 97% Ni.

23. The IC chip of claim 22, wherein the land further comprises:
an adhesion layer in contact with the RDL trace; and
a layer comprising Cu between the layer comprising Ni and the adhesion layer.

24. The IC chip of claim 23, wherein:
the RDL trace has a thickness of 2-10 μm; and
the layer comprising Ni has a thickness less than 5 μm.

25. The IC chip of claim 24, wherein:
the adhesion layer comprises Ti, and has a thickness less than 0.1 μm; and
the seed layer has a thickness less than 0.5 μm.

26. The IC chip of claim 23, wherein:
the front-side land lacks a layer comprising Ni, and comprises a metal layer with a thickness at least twice that of the layer comprising Ni.

27. The IC chip of claim 26, wherein:
the front-side land comprises a metal layer in contact with a front-side trace comprising a Cu alloy, the metal layer having a thickness of at least 10 μm; and
the layer comprising Ni has a thickness less than 5 μm.

28. The IC chip of claim 23, wherein:
the land covers an opening extending through a dielectric layer that is over the RDL trace, and the layer comprising Ni overlaps a portion of the dielectric layers.

29. The IC chip of claim 28, further comprising a layer comprising a noble metal on sidewalls of at least the layer comprising Ni.

30. The IC chip of claim 29, wherein:
the adhesion layer contacts the RDL trace within the opening;
the layer comprising Ni, seed layer, and adhesion layer all overlap the dielectric layers by substantially the same amount along the entire perimeter of the land; and
the noble metal is Au, and the layer comprising the noble metal is on sidewalls of the layer comprising Ni, seed layer, and adhesion layer.

31. An integrated circuit (IC) chip assembly, comprising:
a memory chip further comprising:
a first substrate including a plurality of memory cells;
a first metal trace coupled to one or more of the memory cells, and over a first side of a first substrate; and
a first land between the first metal trace and a first solder joint; and
a microprocessor chip further comprising:
a second substrate including a plurality of transistors;
one or more front-side metallization layers over a front side of the second substrate, the front-side metallization layers electrically coupled to one or more of the transistors;
a front-side land electrically coupled to the front-side metallization layers, and to receive a front-side solder feature;
a through-substrate via (TSV) extending through the second substrate, the TSV with a first end coupled to at least one of the front-side metallization layers;
one or more back-side metallization layers over a back-side of the second substrate, the back-side metallization layers including a metal redistribution layer (RDL) trace electrically coupled to the TSV; and
a back-side land electrically coupled to the back-side metallization layers and connected to the first solder joint, wherein the back-side land is over the RDL trace and includes a layer comprising Ni.

32. The IC chip assembly of claim 31, further comprising a second solder joint comprising Sn, Ag, and Cu in contact with the front-side land, and wherein the front-side land comprises Co.

33. The IC chip assembly of claim 32, wherein:
the first and second solder joints comprise Sn, Ag and Cu;
the RDL trace comprises a Cu alloy;
the layer comprising Ni has purity of at least 97% Ni;
the first land and the front-side land each lack a layer comprising Ni and include a metal layer having a thickness at least twice that of the layer comprising Ni.

34. The IC chip assembly of claim 33, wherein the first land and the front-side land each comprise an electroless metal layer.

35. A method of fabricating an integrated circuit (IC) chip, the method comprising:
receiving a substrate with a back-side redistribution layer (RDL) trace coupled to a through-substrate via (TSV);
depositing one or more dielectric material layers over the RDL trace;
exposing a portion of the RDL trace by etching through the one or more dielectric material layers within a back-side land pattern;
depositing one or more metal seed layers over the exposed portion of the RDL trace and over the dielectric material layers;
patterning a plating mask to have an opening exposing the metal seed layers within the back-side land pattern;
depositing a layer comprising Ni within the opening to form a back-side land over the RDL trace;
stripping the plating mask and seed layers; and
depositing a noble metal layer over the layer comprising Ni.

36. The method of claim 35, further comprising:
forming one or more front-side metallization layers over a front side of the substrate, the front-side metallization layers electrically coupled to one or more of transistors;
forming a front-side land electrically coupled to the front-side metallization layers, and to receive a front-side solder feature;
forming the TSV with a first end coupled to at least one of the front-side metallization layers; and
forming the RDL trace, wherein the RDL trace comprises a Cu alloy of 2-10 μm in thickness, and the layer comprising Ni has purity of at least 97% Ni, and a thickness less than 5 μm.

37. The method of claim 36, wherein:
forming the front-side land further comprises depositing a metal layer comprising other than Ni to a thickness at least twice that of the layer comprising Ni.

38. The method of claim 37, further comprising:
solder bonding the back-side land to a memory chip with a solder comprising Sn, Ag, and Cu; and
solder bonding the front-side land to a host substrate with a solder comprising Sn, Ag, and Cu.

39. The method of claim 35, wherein depositing the one or more metal seed layer further comprises depositing an adhesion layer in contact with the RDL trace, and
depositing a seed layer comprising Cu over the adhesion layer.

40. The method of claim 35, wherein depositing the one or more dielectric material layers further comprises depositing a first dielectric layer with a chemical vapor deposition process, and depositing a photo-definable dielectric layer over the first dielectric layer with a spin-on deposition process; and
wherein exposing a portion of the RDL trace further comprises exposing and developing the land pattern into the photo-definable dielectric layer, and etching through a portion of the first dielectric layer unprotected by the photo-definable dielectric layer with a wet chemical or dry plasma etch process.
